(19) United States
(12) Patent Application Publication
(10) Pub. No.: US 2011/0283521 A1
(43) Pub. Date: Nov. 24, 2011

(54) Electrically powered steering apparatus

(75) Inventor: Yasuo Shimizu, Wako-shi (JP)

(73) Assignee: HONDA MOTOR CO., LTD., Tokyo (JP)

(21) Appl. No.: 13/137,255

(22) Filed: Aug. 1, 2011

Related U.S. Application Data
(63) Continuation of application No. 11/526,717, filed on Sep. 26, 2006.

(30) Foreign Application Priority Data
Sep. 27, 2005 (JP) 2005-280709

(51) Int. Cl. B62D 5/04; H05K 13/04

(52) U.S. Cl. 29/592.1

(57) ABSTRACT

An electrically powered steering apparatus in which at least one torque selected from a steering torque and a motor torque is transmitted from a torque transmission shaft to a rack-and-pinion mechanism to steer steered wheels. The torque transmission shaft has a torque-side shaft provided with a magnetostrictive film of a magnetostrictive sensor for sensing torque; and a pinion shaft provided with a pinion of the rack-and-pinion mechanism. The torque-side shaft and the pinion shaft are separate components which are linked together.

### CROSS-REFERENCE TO RELATED APPLICATION

This application is a Continuation Application of U.S. patent application Ser. No. 11/526,717, filed Sep. 26, 2006; which claims priority to Japanese Application No.: 2005-280709, filed Sep. 27, 2005, the disclosure of each of which is hereby incorporated in its entirety by reference.

### FIELD OF THE INVENTION

The present invention relates to an electrically powered steering apparatus that employs a so-called rack-and-pinion mechanism and is designed to steer the steered wheels of a vehicle by transmitting a motor torque or a steering torque that corresponds to steering to a rack shaft via a rack-and-pinion mechanism.

### BACKGROUND OF THE INVENTION

In recent years, electrically powered steering apparatuses that employ a rack-and-pinion mechanism have come to be widely used in order to reduce the steering force of the steering wheel and provide a pleasant steering response. This kind of electrically powered steering apparatus is designed to transmit both a steering torque and a motor torque, or a steering torque only, to the rack shaft via a torque transmission shaft and a rack-and-pinion mechanism.

The steering torque and the motor torque are sensed by a torque sensor provided to the torque transmission shaft. Magnetostrictive torque sensors, which are torque sensors of relatively simple design that afford high accuracy, are known in the art. Electrically powered steering apparatuses employing magnetostrictive torque sensors are also known, having been disclosed in JP-A-2001-133337 and JP-A-2004-309184.

The conventional electrically powered steering apparatuses disclosed in JP-A-2001-133337 and JP-A-2004-309184 are apparatuses designed to transmit the steering torque of steering the steering wheel from the steering wheel to the rack shaft via a torque transmission shaft and a rack-and-pinion mechanism, wherein the steering torque applied to the torque transmission shaft is sensed by a magnetostrictive torque sensor.

This magnetostrictive torque sensor has a design in which a magnetostrictive film is formed on the outside peripheral face of the torque transmission shaft. In this magnetostrictive torque sensor, changes in magnetostriction produced in the magnetostrictive film in accordance with the steering torque applied to the torque transmission shaft are sensed by a magnetic coil and a magnetostrictive torque sensor circuit, whereby the steering torque is sensed.

In addition to the magnetostrictive film formed on the outside peripheral face, the torque transmission shaft also has the pinion of the rack-and-pinion mechanism, which is formed on an end of the shaft.

It is necessary to be able to steer an automobile even before the engine has been started. In this condition, the steering torque needed to steer the steered wheels is higher than during normal steering. This high steering torque is transmitted from the torque transmission shaft to the rack shaft via the rack-and-pinion mechanism. Consequently, high mechanical strength is required of the rack-and-pinion mechanism. Specifically, the rack-and-pinion mechanism is subjected to various outside forces caused by the reaction force from the pavement, and to moderate outside forces from the steering by the driver. The rack-and-pinion mechanism must have sufficient mechanical strength to be able to assure such occasional steering conditions against the action of these forces.

The pinion of the rack-and-pinion mechanism must adequately assure the strength necessary to transmit a steering torque that corresponds to a high load in excess of the steering torque at normal times. Thus, in many instances, pinions are subjected to surface treatments of various kinds, such as a carburizing process, high-frequency hardening, and other heat treatments, as well as shot peening and the like.

However, subjecting a pinion to a heat treatment results in carbon components being diffused in the surface of the torque transmission shaft that has the pinion. As a result, the surface of the torque transmission shaft becomes readily magnetized. When a pinion is subjected to shot peening or another such surface hardening process, compressive stress remains at the surface of the torque transmission shaft.

The magnetostrictive film formed on the outside peripheral face of the torque transmission shaft is typically composed of an Ni—Fe base alloy film or other magnetostrictive plating material. Such magnetostrictive plating materials are highly susceptible to the effects of magnetism from the torque transmission shaft and the effects of strain in the torque transmission shaft.

In cases in which the torque transmission shaft has both a magnetostrictive film and a pinion in this way, there is room for improvement in terms of enhancing the stability of the magnetostriction characteristics of the magnetostrictive film. Stabilizing the magnetostriction characteristics of the magnetostrictive film leads to stabilization of the sensor signal of the magnetostrictive torque sensor.

There accordingly exists a need for technology whereby a torque transmission shaft can be provided with both a magnetostrictive film and a pinion by means of a process optimal for each, and whereby the stability of the magnetostriction characteristics of the magnetostrictive film can be enhanced.

### SUMMARY OF THE INVENTION

According to the present invention, there is provided an electrically powered steering apparatus wherein at least one torque selected from a steering torque for steering a steering member and a motor torque generated by an electric motor in accordance with steering of the steering member is transmitted to steered wheels via a rack-and-pinion mechanism and a rack shaft, whereby the steered wheels are steered, the apparatus comprising a torque transmission shaft for transmitting the at least one torque to the rack-and-pinion mechanism; and a magnetostrictive torque sensor for sensing the at least one torque transmitted to the torque trans-mission shaft; wherein the torque transmission shaft has a torque-side shaft in which a magnetostrictive film of the magnetostrictive torque sensor is formed on the outside peripheral face thereof; and a pinion shaft provided with a pinion of the rack-and-pinion mechanism, and wherein the torque-side shaft and the pinion shaft are composed of separate members linked together.

In this way, the torque-side shaft and the pinion shaft are separate members linked together. The pinion shaft can be provided with a pinion in a state separated from the torque-side shaft. Consequently, the pinion shaft and the pinion can be subjected to appropriate surface treatments of various kinds, such as a carburizing process or other heat treatment, or shot peening or the like, in order to assure sufficient strength needed for torque transmission.

The magnetostrictive film of the magnetostrictive torque sensor can be formed on an outside peripheral face of the torque-side shaft under optimal conditions while separated from the pinion shaft. For example, a process for stabilizing the shaft material prior to the magnetostrictive plating process, a heat treatment process performed in order to stabilize the magnetostrictive film, a demagnetization process or high-frequency heat treatment process performed in order to establish the direction of magnetostriction in the magnetostrictive film, or other process can be carried out under optimal conditions. Additionally, the magnetostrictive film formed on the torque-side shaft will not be subjected to the effects of magnetism from the pinion shaft or the effects of strain in the pinion shaft.

The torque-side shaft can be tempered separately from the pinion shaft in order to ensure the necessary torsional rigidity and other mechanical strength properties required of the torque-side shaft as such.

In this way, both the magnetostrictive film and the pinion can be formed on the torque transmission shaft by processes appropriate for each, so workability is enhanced. The stability of the magnetostrictive properties of the magnetostrictive film can be increased as well. By increasing the stability of magnetostrictive properties, sensor signals from the magnetostrictive torque sensor can be stabilized to a sufficient extent, and sensor accuracy increased.

As a result, for example, in an electrically powered steering apparatus wherein the steered wheels are steered by the combined torque of the steering torque from the driver and the assisting torque from an electrical motor, the steering torque transmitted to the torque-side shaft can be sensed with consistently good accuracy by the magnetostrictive torque sensor. Consequently, the steering feel of the steering wheel or other steering component can be sufficiently enhanced.

The pinion shaft preferably has a hollow portion in at least one part thereof, and the torque-side shaft preferably has a mating shaft portion that fits with the hollow portion.

The torque-side shaft preferably has a hollow portion in at least one part thereof, and the pinion shaft preferably has a mating shaft portion that fits with the hollow portion.

The hollow portion and the mating shaft portion preferably have a polygonal cross section orthogonal to the axis line of the torque transmission shaft.

The system by which the mating shaft portion fits with the hollow portion is preferably an interference fit system.

A part of the mating shaft portion that fits with the hollow portion preferably has two mating flange portions, and the two mating flange portions are disposed in the lengthwise direction of the mating shaft portion and are adapted to fit with the hollow portion.

The torque-side shaft preferably comprises a tubular shaft having a hollow portion bored therethrough, the pinion shaft has a mating shaft portion that fits with the hollow portion and passes therethrough, the mating shaft portion has a linking portion at a distal end portion thereof that passes through the hollow portion, and the linking portion is linked to the steering member via a swivel joint.

The apparatus preferably comprises a pin for linking together the torque-side shaft and the pinion shaft.

The apparatus preferably comprises a bearing for rotatably supporting the torque transmission shaft, wherein the bearing is clamped between the torque-side shaft and the pinion shaft so as to restrict relative motion in the axial direction.

### BRIEF DESCRIPTION OF THE DRAWINGS

Certain preferred embodiments of the invention shall be described in detail below, by way of example only, with reference to the accompanying drawings, in which:

FIG. 1 is a schematic view of the electrically powered steering apparatus of the invention;

FIG. 2 is a detailed view of the electric motor, torque-side shaft, and rack shaft shown in FIG. 1;

FIG. 3 is a sectional view taken along line 3-3 of FIG. 2;

FIGS. 4A and 4B are views of the torque transmission shaft in FIG. 3 in disassembled and assembled states;

FIG. 5 is a circuit diagram of the magnetostrictive torque sensor shown in FIG. 3;

FIG. 6 is an exploded view showing modified example 1 of the torque transmission shaft of the invention;

FIGS. 7A and 7B are views showing modified example 2 of the torque transmission shaft of the invention in disassembled and assembled states;

FIGS. 8A to 8D are views showing modified example 3 of the torque transmission shaft of the invention in disassembled and assembled states; and

FIG. 9 is a schematic view showing a modified example of the electrically powered steering apparatus of the invention.

### DETAILED DESCRIPTION OF THE PREFERRED EMBODIMENTS

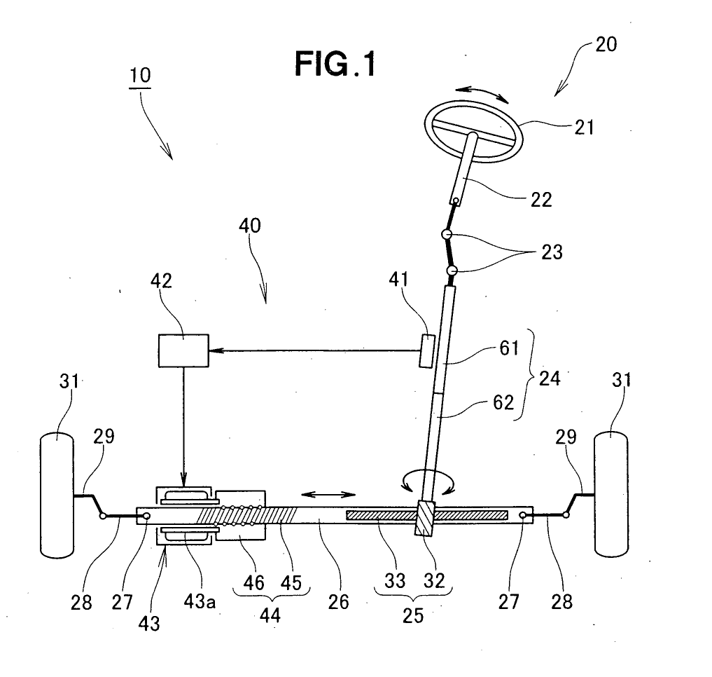

Reference is now made to FIGS. 1 to 5 inclusive, which illustrate an embodiment of the electrically powered steering apparatus. As shown in FIG. 1, the electrically powered steering apparatus 10 comprises a steering system 20 extending from the steering member 22 of the vehicle to steered wheels 31, 31 of the vehicle; and a torque assist mechanism 40 for providing an assist torque to the steering system 20.

The steering member 21 comprises a steering wheel, for example (hereinafter the steering member 21 shall be termed “steering wheel 21” where appropriate). The steered wheels 31, 31 are the left and right front wheels, for example.

The steering system 20 comprises the steering wheel 21; a torque transmission shaft 24 linked to the steering wheel 21 via a steering shaft 22 and swivel joints 23, 23; a rack shaft 26 linked to the torque transmission shaft 24 via a rack-and-pinion mechanism 25; and the left and right steered wheels 31, 31, which are linked to the two ends of the rack shaft 26 via ball joints 27, 27, tie rods 28, 28, and knuckles 29, 29.

The rack-and-pinion mechanism 25 comprises a pinion 32 formed on the torque transmission shaft 24, and a rack 33 formed on the rack shaft 26.

In this way, the electrically powered steering apparatus 10 transmits a steering torque corresponding to steering of the steering wheel 21 by the driver. The torque is transmitted to the rack shaft 26 via the torque trans-mission shaft 24 and the rack-and-pinion mechanism 25, whereby the steered wheels 31, 31 are steered via the rack shaft 26.

The torque assist mechanism 40 comprises a magnetostrictive torque sensor 41, a controller 42, an electric motor 43, and a ball screw 44. The magnetostrictive torque sensor 41 senses the steering torque of the steering system 20 exerted on the steering wheel 21. The controller 42 generates a control signal on the basis of the torque sensor signal of the magnetostrictive torque sensor 41.

On the basis of the control signal of the controller 42, the electric motor 43 generates a motor torque (assist torque) that corresponds on the steering torque. The motor shaft 43a of the electric motor 43 comprises a hollow shaft that surrounds the rack shaft 26.

The ball screw 44 is a power transmission mechanism for transmitting a motor torque to the rack shaft 26, and comprises a thread section 45, a nut 46, and a number of balls. The thread section 45 is formed in the portion of the rack shaft 26 that excludes the area where the rack 33 is located. The nut 46 is a rotary member attached to the thread section 45 via the balls, and is also linked to the motor shaft 43a.

With this electrically powered steering apparatus 10, a steering torque transmitted to the torque transmission shaft 24 can be detected by the magnetostrictive torque sensor 41; a motor torque that corresponds to the steering torque can be generated by the electric motor 43; and this motor torque can be transmitted to the rack shaft 26. The steered wheels 31, 31 are steered via the rack shaft 26 by the combined torque of the steering torque and the additional motor torque generated by the electric motor 43.

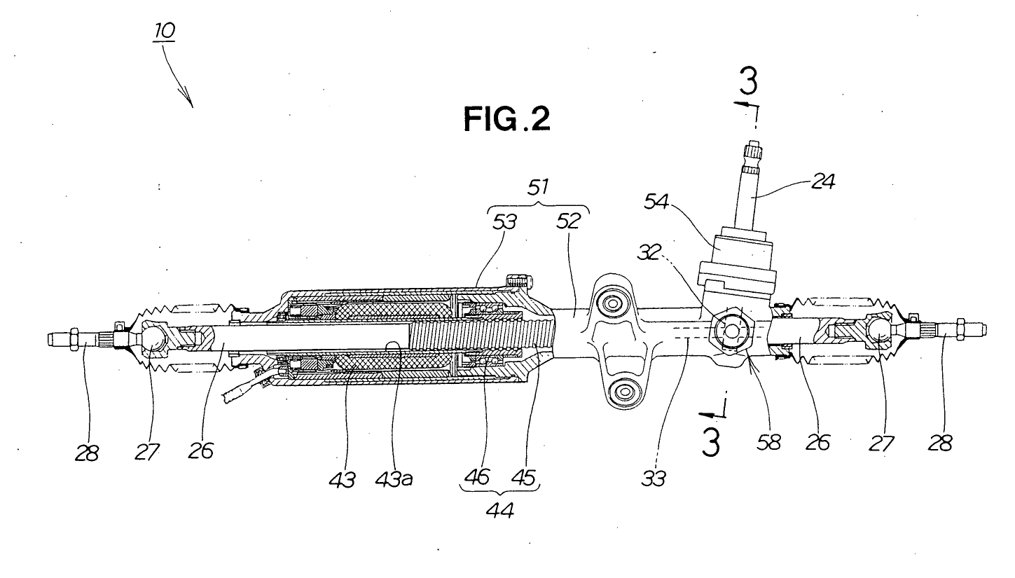

As shown in FIG. 2, the rack 26 is housed within a housing 51 that extends in the sideways direction (left-right direction) of the vehicle. The housing 51 is composed of a substantially tubular first housing 52 and second housing 53 each joined together at one end face and fastened with a bolt, producing a single elongated gear box assembly. The second housing 53 also serves as the motor case for the electric motor 43.

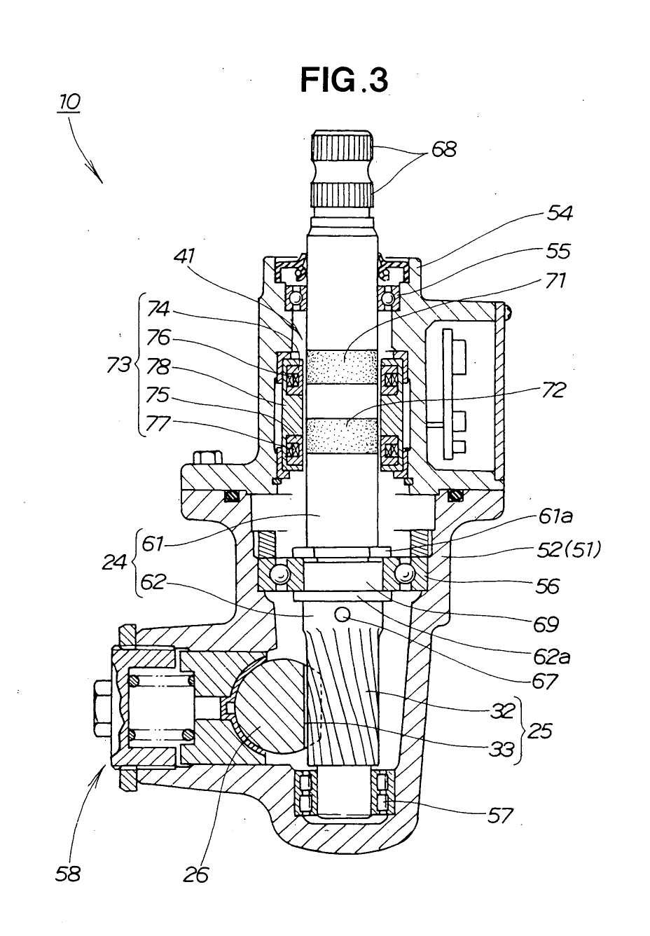

As shown in FIGS. 2 and 3, the torque transmission shaft 24, the rack-and-pinion mechanism 25, the magnetostrictive torque sensor 41, the electric motor 43, and the ball screw 44 are housed within the housing 51. An upper opening in the first housing 52 is covered by a lid 54. The upper end portion, lengthwise center portion, and lower end portion of the torque transmission shaft 24 are rotatably supported on the first housing 52 via three bearings 55, 56, 57 at top and bottom.

The first housing 52 is also provided with a rack guide 58. The rack guide 58 slidably supports the rack shaft 26 in the axial direction while restricting the motion of the rack shaft 26 in the lengthwise direction of the torque transmission shaft 24, and restricting the motion of the rack shaft 26 in the direction of disengagement of the pinion 32 and the rack 33.

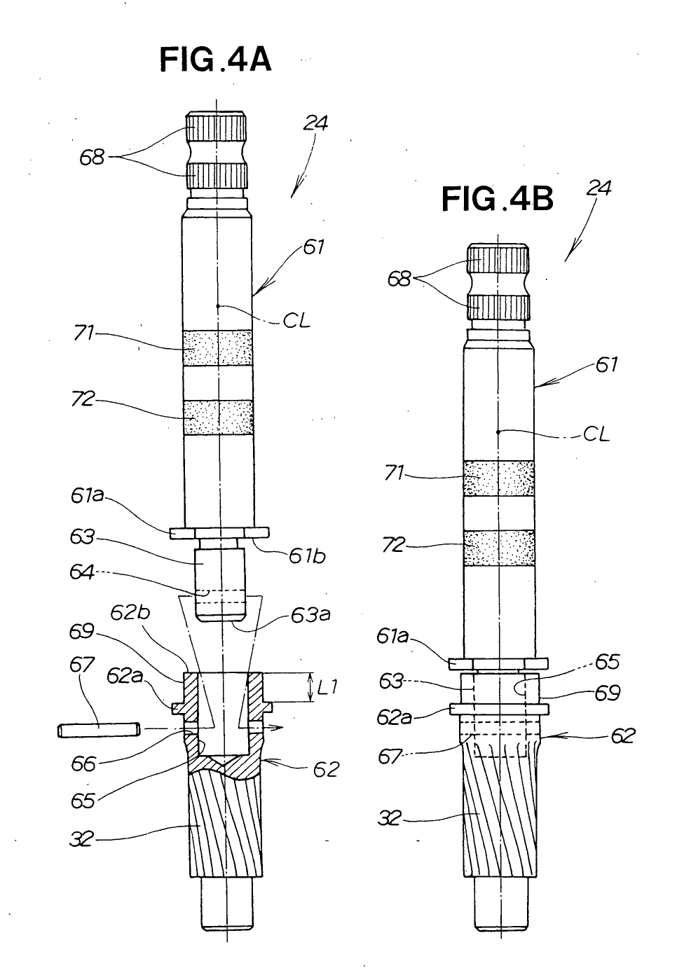

Next, the torque transmission shaft 24 shall be described in detail on the basis of FIGS. 3, 4A, and 4B. FIG. 4A shows the torque transmission shaft in a disassembled state. FIG. 4B shows the torque transmission shaft 24 in the assembled state.

As shown in FIGS. 4A and 4B, the torque transmission shaft 24 comprises a torque-side shaft 61 and a pinion shaft 62. The torque-side shaft 61 and the pinion shaft 62 are composed of mutually separate members, which are arrayed on the same center axis (i.e., on the axial line CL of the torque transmission shaft 24). The torque-side shaft 61 and the pinion shaft 62 are integrally assembled by being fitted and linked together. The torque-side shaft 61 and the pinion shaft 62 are each made from a magnetic body such as ferromagnetic material. An example of a ferromagnetic material is steel (including nickel-chromium-molybdenum steel materials).

The torque-side shaft 61 is a solid shaft having the two magnetostrictive films 71, 72 of the magnetostrictive torque sensor 41 formed on the outside peripheral face thereof. Where appropriate, the magnetostrictive film 71 shall be termed the “first residual strain portion.” Also, the magnetostrictive film 72 shall be termed the “second residual strain portion” where appropriate.

A flange section 61a, a mating shaft portion 63, a pin hole 64, and a linking portion 68 are integrally formed with the torque-side shaft 61. The flange section 61a, mating shaft portion 63, and linking portion 68 are arrayed along the axis line CL.

The mating shaft portion 63 is a shaft of a relatively small-diameter circular rod shape extending from one end face 61b of the torque-side shaft 61 to the other end face 62b of the pinion shaft 62. The flange section 61a is a portion of a substantially hexagonal shape formed at the one end face 61b of the torque-side shaft 61, i.e., at the basal end part of the mating shaft portion 63. The pin hole 64 is a through-hole that passes through the mating shaft portion 63 and that passes through the axis line CL in a direction orthogonal to the axis line CL. The linking portion 68 is a portion that links the swivel joint 23 (see FIG. 1) to the other end of the torque-side shaft 61, and is composed of serrations, for example.

The pinion shaft 62 is a solid shaft having a pinion 32 formed at one end, and also having formed thereon a flange section 62a, a mating hole 65, a pin hole 66, and a supported portion 69. The flange section 62a, mating hole 65, and supported portion 69 are arrayed along the axis line CL.

The mating hole 65 takes the form of a bottomed, circular hole that is made in the pinion shaft 62 and opens onto the other end face 62b thereof, which faces the distal end face of the mating shaft portion 63. That is, the mating hole 65 is a hollow portion formed in at least a part of the pinion shaft 62 in order to fit with the mating shaft portion 63. The diameter of the mating hole 65 is smaller than the diameter of the supported portion 69.

The pin hole 66 is a through-hole that is disposed at the location of the mating hole 65 in the pinion shaft 62 and passes therethrough in a direction orthogonal to the axis line CL, and also passes through the axis line CL. This pin hole 66 also passes through the mating hole 65. The location of the pin hole 66 is established at a location that is aligned with the pin hole 64 when the mating shaft portion 63 has been fitted within the mating hole 65.

The supported portion 69 is a portion that is formed on the outside peripheral face of the pinion shaft 62 and that extends over a given length L1 towards the pinion 32 end from the other end face 62b. This supported portion 69 is rotatably supported by the bearing 56 (see FIG. 3)

The flange section 62a is a substantially circular portion formed at a location disposed away from the other end face 62b of the pinion shaft 62 by the length L1, i.e., disposed in the basal end part of the supported portion 69.

The procedure for assembling the torque-side shaft 61 and the pinion shaft 62 is as follows.

First, as shown in FIG. 4A, a lower hole is drilled in the pinion shaft 62 at the location of the pin hole 66. The lower hole is a through-hole drilled prior to drilling the regular pin hole 66, and is slightly smaller in diameter than the pin hole 66. Drilling the lower hole in advance can afford improved processability in the drilling process during subsequent drilling of the regular pin hole 66. At this point in time, the pin hole 64 or a lower hole for the pin hole 64 has yet to be drilled in the mating shaft portion 63.

Next, the bearing 56 is fitted onto the supported portion 69 of the pinion shaft 62 (see FIG. 3), and one end face of the inner ring of the bearing 56 is positioned in contact against the end face of the flange portion 62a. By so doing, the bearing 56 can be attached to the pinion shaft 62.

Next, the mating shaft portion 63 is fitted into the mating hole 65. The end face of the flange section 61a is then positioned in contact against the other end face of the inner ring in the bearing 56. As a result, as shown in FIG. 3, the two ends of the inner ring of the bearing 56 are sandwiched by the two flange sections 61a, 62a.

Next, with the mating shaft portion 63 fitting into the mating hole 65, the regular pin hole 66 is drilled passing through the pinion shaft 62 at the location of the predrilled lower hole. At the same time that the pin hole 66 passing through the pinion shaft 62 is drilled, the pin hole 64 is drilled through the mating shaft portion 63 as well. The diameter of these pin holes 64, 66 is slightly larger than the diameter of the lower hole.

Next, a pin 67 is forced into the pin holes 64, 66. This completes the assembly procedure of the torque transmission shaft 24.

By integrally linking together the torque-side shaft 61 and the pinion shaft 62 by means of the pin 67 in the manner shown in FIG. 4B, the components can be assembled into a single torque transmission shaft 24. A simple pin 67 suffices to integrally link the torque-side shaft 61 and the pinion shaft 62, allowing the components to be linked by a simple mechanism.

Additionally, the two ends of the inner ring of the bearing 56 are sandwiched by the two flange sections 61a, 62a. The bearing 56 is attached to the torque transmission shaft 24. In this way, the bearing 56 is sandwiched between the torque-side shaft 61 and the pinion shaft 62 so as to limit relative movement in the axial direction. Consequently, the bearing 56 can be easily and accurately positioned with respect of the torque transmission shaft 24. Additionally, the bearing 56 will not come apart from the torque trans-mission shaft 24.

The torque-side shaft 61 and pinion shaft 62 assembled in this way restrict one another in terms of relative rotation and relative movement in the axial direction. A steering torque transmitted from the steering wheel 21 (see FIG. 1) to the torque-side shaft 61 is transmitted from the torque-side shaft 61 to the pinion shaft 62 via the pin 67.

Next, the magnetostrictive torque sensor 41 shall be described in detail. As shown in FIG. 3, the magnetostrictive torque sensor 41 comprises the first and second residual strain portions 71, 72 and a sensor 73. The first and second residual strain portions 71, 72 are imparted with residual strain and are disposed on the torque-side shaft 61, and the magnetostriction characteristics of these sections change depending on the torque acting thereon. The sensor 73 is disposed surrounding the first and second residual strain portions 71, 72. The sensor electronically senses the magnetostriction effect produced by the first and second residual strain portions 71, 72 and outputs a sensor signal. This sensor signal is the torque sensor signal.

In still greater detail, the first and second residual strain portions 71, 72 are a pair of magnetic anisotropic members imparted with residual strain in mutually opposite directions in the axial lengthwise direction of the torque-side shaft 61, and take the form of magnetostrictive films formed on the surface of the torque-side shaft 61.

The two magnetostrictive films (first and second residual strain portions 71, 72) are made of a material that exhibits a large change in flux density with respect to a change in strain; for example, films formed from an Ni—Fe base alloy by a vapor plating process on the outside peripheral face of the torque-side shaft 61. The alloy film preferably has a thickness of about 5 to 20 μm. However, the thickness of the alloy film may be less or greater than this range.

In cases in which the Ni—Fe base alloy film includes nickel at a level of about 20 wt % or about 50 wt %, the magnetostriction constant will be quite high, and thus the magnetostriction effect will be enhanced. Consequently, a material having a nickel content of about 20 wt % or about 50 wt % is preferably used for the Ni—Fe base alloy film. For example, a material having 50 to 60 wt % Ni, with the balance being Fe, is used for the Ni—Fe base alloy film. It is sufficient for the magnetostrictive film to be a ferroelectric film, and a Permalloy (Ni: about 78 wt %, Fe: balance) or Supermalloy (Ni: about 78 wt %, Mo: 5 wt %, Fe: balance) film is acceptable. Here, Ni denotes nickel, Fe denotes iron, and Mo denotes molybdenum.

Meanwhile the sensor 73 comprises cylindrical coil bobbins 74, 75 through which the torque-side shaft 61 is passed; a first multilayer solenoid winding 76 and a second multilayer solenoid winding 77 that are wound onto the coil bobbins 74, 75; and a back yoke 78 for use as a magnetic shield, disposed surrounding the perimeter of the first and second multilayer solenoid windings 76, 77.

The first and second multilayer solenoid windings 76, 77 are sensor coils. Hereinafter the first multilayer solenoid winding 76 shall be referred to as the first sensor coil 76. The second multilayer solenoid winding 77 shall be referred to as the second sensor coil 77. The first sensor coil 76 is wound about the perimeter of the first residual strain portion 71 so as to have a gap. The second sensor coil 77 is wound about the perimeter of the second residual strain portion 72 so as to have a gap.

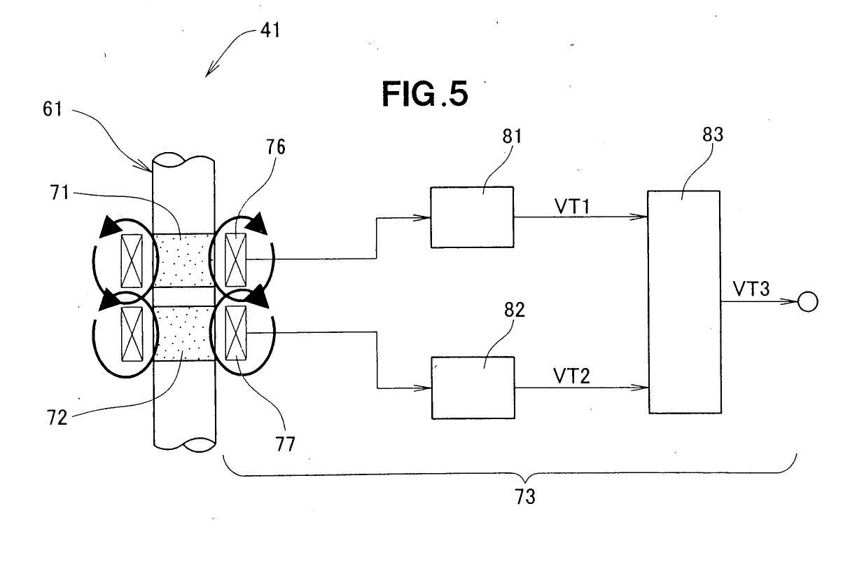

As shown in FIG. 5, the sensor 73 additionally has first and second conversion circuits 81, 82 and a torque signal output circuit 83. The first conversion circuit 81 commutates, amplifies, and converts the sensor signal of the first sensor coil 76, whereupon the signal is output as a sensor voltage VT1. The second conversion circuit 82 commutates, amplifies, and converts the sensor signal of the second sensor coil 77, whereupon the signal is output as a sensor voltage VT2. The torque signal output circuit 83 calculates the sensor voltages VT1, VT2 and outputs a torque sensor voltage VT3.

The action of the sensor 73 is as follows. The first and second sensor coils 76, 77 sense the torsion produced in the torque-side shaft 61 in accordance with a steering torque, and issue sensor signals. These sensor signals are output as sensor voltages VT1, VT2 by the first and second conversion circuits 81, 82. The sensor voltages VT1, VT2 are output as torque sensor voltage VT3 by the torque signal output circuit 83. The torque sensor voltage VT3 is a torque sensor signal (steering torque signal).

The description of the magnetostrictive torque sensor 41 may be summarized as follows. The torque-side shaft 61 has magnetostrictive films 71, 72 imparted with strain. When torque acts on the magnetostrictive films 71, 72 via a torque-side shaft 61, the magnetic permeability of the magnetostrictive films 71, 72 changes according to this torque. The impedance (induction voltage, sensor voltage) in the first and second sensor coils 76, 77 changes according to the change in magnetic permeability. By detecting such a change of impedance, the direction of torque and the value of torque acting on the torque-side shaft 61 can be sensed.

The description of the preceding embodiment may be summarized as follows. As shown in FIGS. 4A and 4B, the torque-side shaft 61 and the pinion shaft 62 are mutually separate members which are linked together.

The pinion 32 can be formed with the pinion shaft 62 separated from the torque-side shaft 61. Consequently, the pinion shaft 62 and the pinion 32 can be subjected to appropriate surface treatments of various kinds, such as a carburizing process or other heat treatment, or shot peening or the like, in order to assure sufficient strength needed for torque transmission.

Meanwhile, the magnetostrictive films 71, 72 can be formed under optimal conditions on the outside peripheral face of the torque-side shaft 61 while separated from the pinion shaft 62. For example, a process for stabilizing the shaft material prior to the magnetostrictive plating process, a heat treatment process performed in order to stabilize the magnetostrictive films 71, 72, a demagnetization process or high-frequency heat treatment process performed in order to establish the direction of magnetostriction in the magnetostrictive films 71, 72, or other process can be carried out under optimal conditions. Additionally, the magnetostrictive films 71, 72 formed on the torque-side shaft will not be subjected to the effects of magnetism from the pinion shaft 62 or the effects of strain in the pinion shaft 62.

Further, the torque-side shaft 61 can be tempered separately from the pinion shaft 62 in order to ensure the necessary torsional rigidity and other mechanical strength properties required of this shaft 61 as such.

In this way, both the magnetostrictive films 71, 72 and the pinion 32 can be formed on the torque transmission shaft 24 by processes appropriate for each. The stability of the magnetostrictive properties of the magnetostrictive films 71, 72 can be increased as well. By increasing the stability of magnetostrictive properties, sensor signals from the magnetostrictive torque sensor 41 (see FIG. 1) can be stabilized to a sufficient extent, and sensor accuracy increased.

As a result, a steering torque transmitted to the torque transmission shaft 24 can be sensed with consistently good accuracy by the magnetostrictive torque sensor 41. Consequently, the steering feel of the steering wheel or other steering component 21 can be sufficiently enhanced.

Next, modified examples of the torque transmission shaft 24 shall be described. Arrangements that are the same as those in the embodiment shown in FIG. 4 are assigned identical symbols and shall not be discussed.

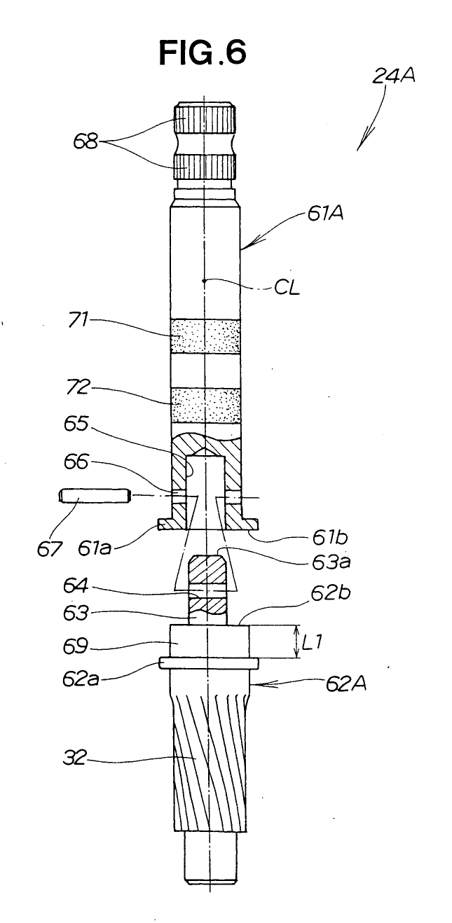

First, modified example 1 of the torque transmission shaft 24 shall be described on the basis of FIG. 6. A feature of the torque transmission shaft 24A of modified example 1 is that the placement of the mating shaft portion 63 and the mating hole 65 is the reverse of that in the embodiment shown in FIGS. 4A and 4B.

In greater detail, the torque transmission shaft 24A of modified example 1 is substantially identical in design to the torque transmission shaft 24 of the embodiment, and comprises a torque-side shaft 61A and a pinion shaft 62A.

The torque-side shaft 61A of modified example 1 has a mating hole 65 in place of the mating shaft portion 63, as well as having a pin hole 66, but is otherwise substantially identical in design to the torque-side shaft 61 of the embodiment (see FIG. 4A). The mating hole 65 takes the form of a bottomed, circular hole that opens onto the other end face 61b of the torque-side shaft 61A. That is, the mating hole 65 is a hollow portion formed in at least a part of the torque-side shaft 61A in order to fit with the mating shaft portion 63.

The pinion shaft 62A of modified example 1 has a mating shaft portion 63 in place of the mating hole, as well as having a pin hole 64, but is otherwise substantially identical in design to the pinion shaft 62 of the embodiment (see FIG. 4A). The mating shaft portion 63 extends towards the opening of the mating hole 65 from the other end face 62b of the pinion shaft 62A.

The assembly procedure for the torque-side shaft 61A and the pinion shaft 62A is as follows.

First, as shown in FIG. 6, a lower hole is drilled in the torque-side shaft 61A at the location of the pin hole 66. At this point in time, the pin hole 64 or a lower hole for the pin hole 64 have yet to be drilled in the mating shaft portion 63.

Next, the bearing 56 is fitted onto the supported portion 69 (see FIG. 3), and one end face of the inner ring of the bearing 56 is positioned in contact against the end face of the flange portion 62a. By so doing, the bearing 56 can be attached to the pinion shaft 62A.

Next, the mating shaft portion 63 is fitted into the mating hole 65. The end face of the flange section 61a is then positioned in contact against the other end face of the inner ring in the bearing 56. As a result, as shown in FIG. 3, the two ends of the inner ring of the bearing 56 are sandwiched by the two flange sections 61a, 62a.

Next, with the mating shaft portion 63 fitting into the mating hole 65, the regular pin hole 66 is drilled passing through the torque-side shaft 61A at the location of the predrilled lower hole. At the same time that the pin hole 66 passing through the torque-side shaft 61A is drilled, the pin hole 64 is drilled through the mating shaft portion 63 as well. The diameter of these pin holes 64, 66 is slightly larger than the diameter of the lower hole.

Next, the pin 67 is forced into the pin holes 64, 66. By integrally linking together the torque-side shaft 61A and the pinion shaft 62A by means of the pin 67, the components can be assembled into a single torque transmission shaft 24A. The two ends of the inner ring of the bearing 56 are sandwiched by the two flange sections 61a, 62a. The bearing 56 is attached to the torque transmission shaft 24A. The bearing 56 will not come apart from the torque transmission shaft 24A. This completes the assembly operation of the torque transmission shaft 24A.

The torque-side shaft 61A and pinion shaft 62A assembled in this way restrict one another in terms of relative rotation and relative movement in the axial direction. A steering torque transmitted from the steering wheel 21 (see FIG. 1) to the torque-side shaft 61A is transmitted from the torque-side shaft 61A to the pinion shaft 62A via the pin 67.

Modified example 1 affords working effects analogous to those of the embodiment shown in FIGS. 1 to 5. In modified example 1, the torque-side shaft 61A is composed of a shaft having a hollow portion 65 formed in at least a section thereof, while the pinion shaft 62A is composed of a solid shaft that fits with the hollow portion 65 (i.e., has a mating shaft portion 63). The effects of the shaft interior of torque-side shaft 61A, such as dispersion of magnetization or heat treatment, on the magnetostrictive films 71, 72 can therefore be minimized.

After the bearing 56 has been installed on the supported portion 69 (see FIG. 3), and the torque-side shaft 61A and pinion shaft 62A have been fitted and fastened together, the supported portion 69 and the bearing 56 will be unaffected by the load at that time. For example, the supported portion 69 will not experience an increase in diameter. Consequently, the bearing 56 can be attached more stably to the supported portion 69. Additionally, the torque-side shaft 61A and the pinion shaft 62A can be linked more stably.

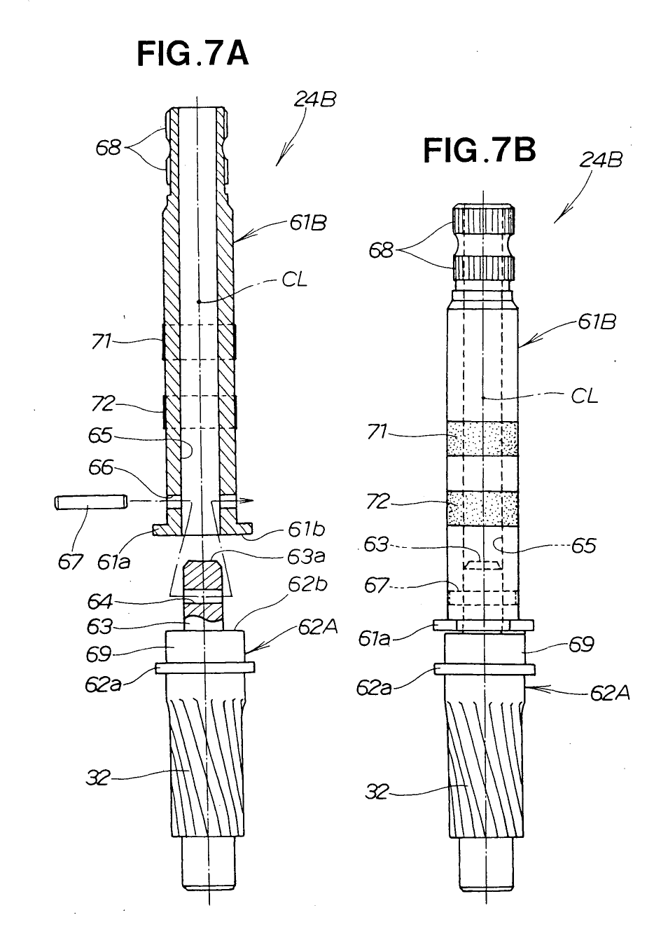

Next, another modified example 2 of the torque transmission shaft 24 shall be described on the basis of FIGS. 7A and 7B. FIG. 7A shows the torque transmission shaft 24B in a disassembled state. FIG. 7B shows the torque transmission shaft 24B in an assembled state.

The torque transmission shaft 24B of modified example 2 is a further variation example of modified example 1 shown in FIG. 6, and is configured so that the mating hole 65 (hollow portion 65) formed in the center of the torque-side shaft 61B is a through-hole.

In greater detail, the torque transmission shaft 24B of modified example 2 is substantially identical in design to the torque-side shaft 61A of modified example 1, and comprises a torque-side shaft 61B and a pinion shaft 62B. Apart from the fact that the torque-side shaft 61B of modified example 2 is a round cylindrical shaft, i.e., a hollow shaft, the design is otherwise substantially identical to that of the torque-side shaft 61A of modified example 1 (see FIG. 6). The pinion shaft 62A is identical in design to that of modified example 1. By fitting the hollow mating shaft portion 63 into the mating hole 65, the components can be assembled into a single torque transmission shaft 24B.

In other respects the design is the same as that of modified example 1 shown in FIG. 6. Arrangements that are the same as those in modified example are assigned identical symbols and shall not be discussed.

Modified example 2 affords working effects analogous to those of the embodiment shown in FIGS. 1 to 5. Additionally, according to modified example 2, the torque-side shaft 61B is composed by a shaft in which a hollow portion 65 is formed through the entire axial length thereof, and the pinion shaft 62A is composed of a solid shaft that fits with the hollow portion 65. The effects of the interior of the torque-side shaft 61A, such as dispersion of magnetization or heat treatment, on the magnetostrictive films 71, 72 can therefore be minimized.

Also, according to modified example 2, the bearing 56 can be attached more stably to the supported portion 69, and the torque-side shaft 61B and pinion shaft 62B can be linked more stably in the same manner as in modified example 1.

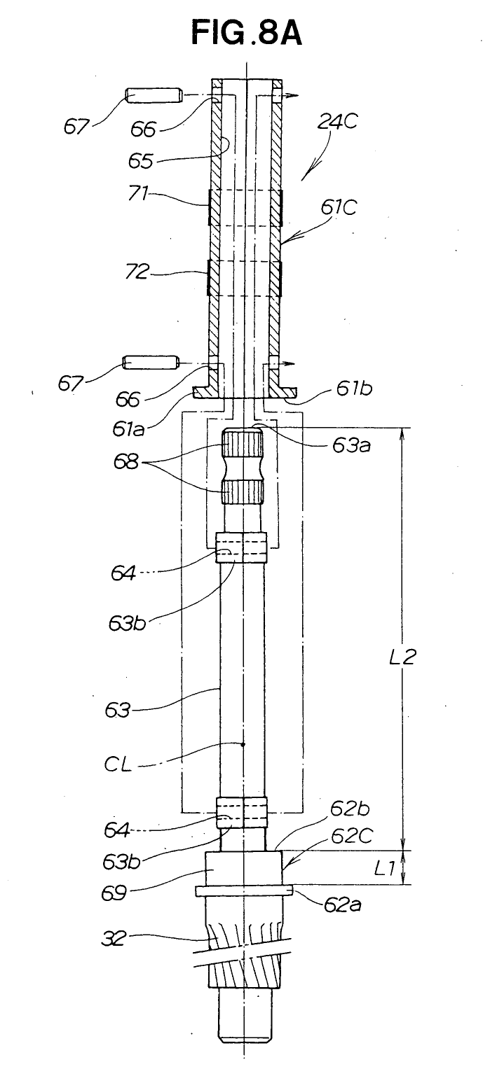

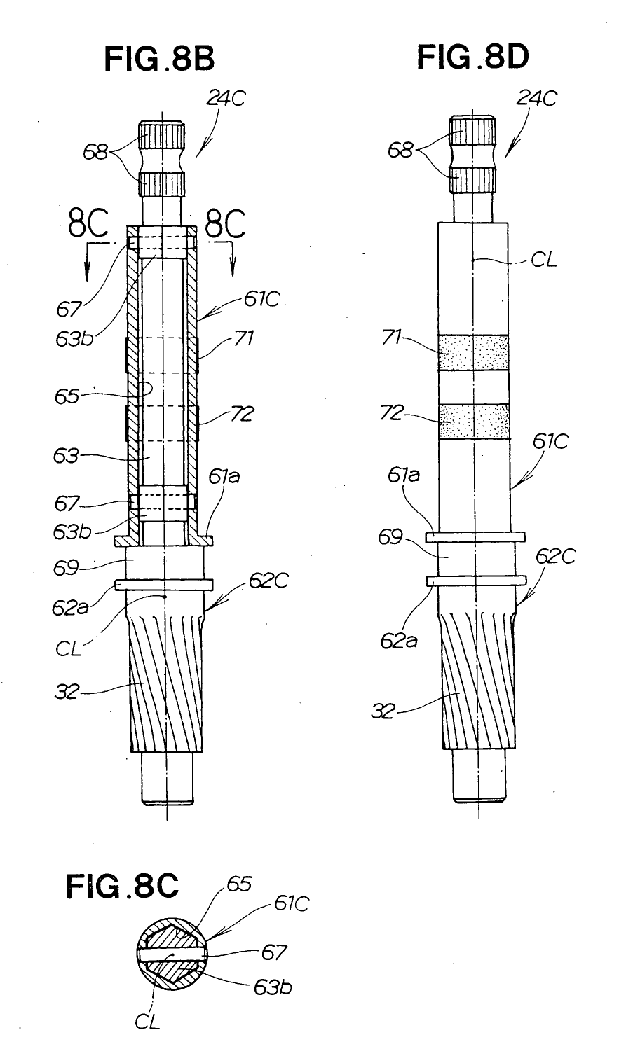

Next, another modified example 3 of the torque transmission shaft 24 shall be described on the basis of FIGS. 8A to 8D. FIG. 8A shows a torque transmission shaft 24C in a disassembled state. FIG. 8B shows the cross sectional structure of the torque transmission shaft 24C in an assembled state. FIG. 8C shows the cross sectional structure taken along line 8C-8C in FIG. 8B. FIG. 8D is an exterior view the torque transmission shaft 24C in the assembled state.

The torque transmission shaft 24C of modified example 3 is a further variation example of modified example 2 shown in FIGS. 7A and 7B, and comprises a torque-side shaft 61C and a pinion shaft 62C. The torque-side shaft 61C is equivalent to the torque-side shaft 61B of modified example 2 (see FIG. 7A) and comprises a hollow shaft. The pinion shaft 62C is equivalent to the pinion shaft 62B of modified example 2 (see FIG. 7A) and comprises a solid shaft that fits with the hollow shaft.

In greater detail, the torque-side shaft 61C is a hollow shaft having a mating hole 65 (hollow portion 65) formed on the axis line CL, as shown in FIG. 8A. The contour of the hollow shaft is circular. As shown in FIG. 8C, the mating hole 65 is a through-hole in which a cross section orthogonal to the axis line CL is of polygon shape (e.g., a regular hexagon shape).

Additionally, the torque-side shaft 61C has one aforementioned pin hole 66 in proximity to each of the two ends thereof. The pin holes 66, 66 are through-holes that are orthogonal to the axis line CL and that pass through the axis line CL. The pin holes 66 also pass through the mating hole 65. The torque-side shaft 61C lacks the linking portion 68 of modified example 2 (see FIG. 7A).

Meanwhile, the pinion shaft 62C of modified example 3 has a mating shaft portion 63 of greater length than does the pinion shaft 62A of modified example 2 (see FIG. 7A). The total length L2 of the mating shaft portion 63 is greater than the total length of the torque-side shaft 61C.

The mating shaft portion 63 passes through the mating hole 65 and has a linking portion 68 at the distal end thereof projecting out from the mating hole 65. Further, the mating shaft portion 63 has one integrally formed mating flange portion 63b formed in proximity to each lengthwise end thereof.

As shown in FIG. 8A, the two mating flange portions 63b, 63b are protruding sections that are larger in diameter than the mating shaft portion 63 and that are formed extending all the way around the circumference of the mating shaft portion 63. As shown in FIGS. 8A and 8C, the mating flange portions 63b, 63b are formed with a polygonal cross section identical to that of the mating hole 65, and each have one aforementioned pin hole 64. The pin holes 64, 64 are through-holes that are orthogonal to the axis line CL and that pass through the axis line CL. The locations of the two pin holes 64, 64 and the two mating flange portions 63b, 63b are established at locations aligning with the two pin holes 66, 66 when the mating shaft portion 63 has been fitted with the mating hole 65.

The system by which the mating flange portions 63b, 63b of the pinion shaft 62C is fitted with respect to the mating hole 65 is an interference fit system. An “interference fit” is a fit system wherein the hole and shaft fit together so as to normally give rise to interference during assembly; i.e., either the maximum diameter of the hole is smaller than the minimum diameter of the shaft, or in the extreme case, the diameters are equal. “Interference” refers, in the case of the shaft diameter greater than the hole diameter, to the difference in diameter of the hole with respect to the diameter of the shaft prior to assembly.

In modified example 3, appropriate “interference” has been established between the mating flange portions 63b, 63b and the mating hole. By fitting the mating flange portions 63b, 63b into the mating hole, a given load can be applied in the diametrical direction to the torque-side shaft 61C. By means of this load, dispersion of the magnetostriction characteristics of the magnetostrictive films 71, 72 can be restricted.

The assembly procedure for the torque-side shaft 61C and the pinion shaft 62C is as follows.

First, as shown in FIG. 8A, a lower hole is drilled in the torque-side shaft 61C at the location of each pin hole 66, 66. At this point in time, the pin holes 64, 64 or lower holes for the pin holes 64, 64 have yet to be drilled in the mating shaft portion 63.

Next, the bearing 56 is fitted onto the supported portion 69 (see FIG. 3), and one end face of the inner ring of the bearing 56 is positioned in contact against the end face of the flange portion 62a. By so doing, the bearing 56 can be attached to the pinion shaft 62C.

Next, the mating flange portions 63b, 63b are fit into the mating hole 65 while passing the mating shaft portion 63 therethrough. The end face of the flange section 61a is then positioned in contact against the other end face of the inner ring in the bearing 56. As a result, as shown in FIGS. 3 and 8B, the two ends of the inner ring of the bearing 56 are sandwiched by the two flange sections 61a, 62a.

Next, with the mating flange portions 63b, 63b fitting into the mating hole 65, the regular pin holes 66, 66 are drilled passing through the torque-side shaft 61C at the location of the predrilled lower holes. At the same time that the pin holes 66, 66 passing through the torque-side shaft 61C are drilled, the pin holes 64, 64 are drilled through the mating flange portions 63b, 63b as well. The diameter of these pin holes 64, 64, 66, 66 is slightly greater than the diameter of the lower holes.

Next, the pins 67, 67 are forced into the pin holes 64, 64, 66, 66. By integrally linking together the torque-side shaft 61C and the pinion shaft 62C by means of the pins 67, 67, the components can be assembled into a single torque transmission shaft 24C. Further, the two ends of the inner ring of the bearing 56 are sandwiched by the two flange sections 61a, 62a. The bearing 56 is attached to the torque transmission shaft 24C. The bearing 56 will not come apart from the torque transmission shaft 24C. This completes the assembly operation of the torque transmission shaft 24C.

The torque-side shaft 61C and pinion shaft 62C assembled in this way restrict one another in terms of relative rotation and relative movement in the axial direction. A steering torque transmitted from the steering wheel 21 (see FIG. 1) to the torque-side shaft 61C is transmitted from the torque-side shaft 61C to the pinion shaft 62C via the pins 67, 67.

The mating hole 65 and the mating flange portions 63b, 63b have a polygonal cross section. The steering torque is transmitted from the torque-side shaft 61C to the pinion shaft 62C via these polygonally shaped mating portions.

Modified example 3 affords working effects analogous to those of the embodiment shown in FIGS. 1 to 5. In modified example 3, the torque-side shaft 61C is composed of a shaft in which a hollow portion 65 is formed through the entire axial length thereof, and the pinion shaft 62C is composed of a solid shaft that fits with the hollow portion 65. The effects of the interior of the torque-side shaft 61C, such as dispersion of magnetization or heat treatment, on the magnetostrictive films 71, 72 can therefore be minimized.

Also, according to modified example 3, the bearing 56 can be attached more stably to the supported portion 69, and the torque-side shaft 61C and pinion shaft 62C can be linked more stably in the same manner as in modified example 1.

The torque-side shaft 61C is a hollow shaft having a mating hole 65 of a polygonal cross section. The torque-side shaft 61C can be manufactured by the following process. First, a long hollow shaft having a mating hole 65 of a polygonal cross section is provided. Next, a magnetostrictive film is formed over the entire outside peripheral face of this hollow shaft. Next, the hollow shaft is cut to the required length. Next, the magnetostrictive film is imparted with anisotropy at a plurality of suitable locations of the cut hollow shaft. This completes manufacture of the torque-side shaft 61C.

By manufacturing the torque-side shaft 61C by this process, torque-side shafts 61C having multiple magnetostrictive films can be mass-produced. Since the number of manufacturing steps can be appreciably reduced, cost of the torque-side shaft 61 can be reduced.

In modified example 3, since the mating hole 65 and the mating flange portions 63b, 63b have polygonal cross sections, it is possible for a steering torque to be transmitted by these polygonally shaped mating portions. It is accordingly possible to dispense with the pins 67, 67 and so reduce the number of parts. However, in cases in which the pins 67, 67 are dispensed with, it will be necessary to restrict relative axial motion of the torque-side shaft 61C and the pinion shaft 62C.

Also, in modified example 3, the cross sectional shape of the mating hole 65 and the mating flange portions 63b, 63b is not limited to a hexagonal shape, and may be circular instead. A circular cross section makes it easier to manage accuracy and fitting, making manufacture easier as well. Particularly in cases in which the “interference fit” system is employed for the mating hole 65 and the mating flange portions 63b, 63b, a circular cross sectional shape of the mating hole 65 and the mating flange portions 63b, 63b will afford even greater ease of manufacture.

The fit system of the mating hole 65 and the mating flange portions 63b, 63b is not limited to “interference fit,” and it is possible to employ some other system.

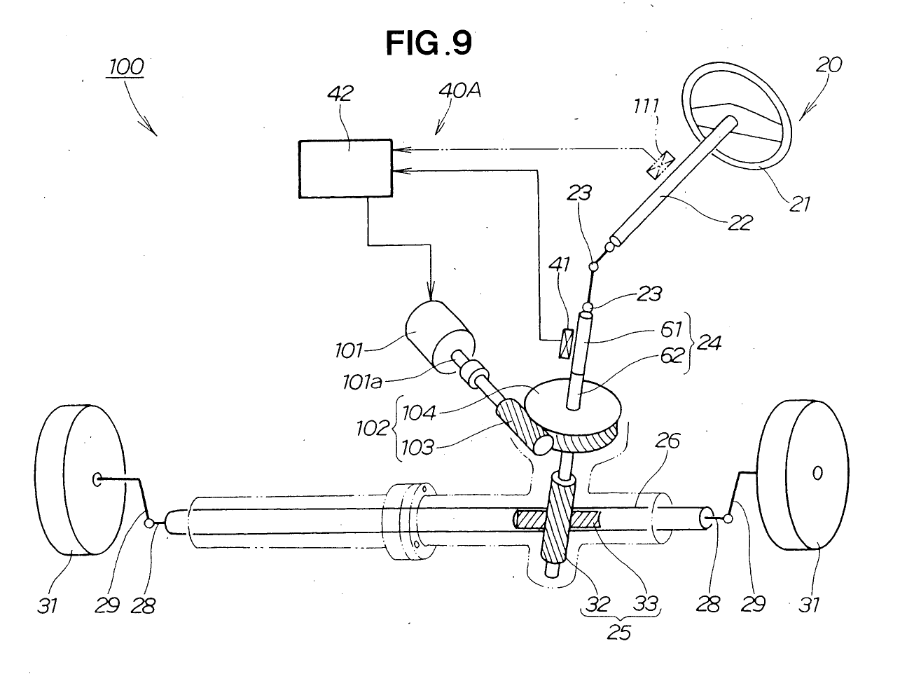

Next, another variation example of the electrically powered steering apparatus 10 shall be described based on FIG. 9. Arrangements that are the same as those in the embodiment shown in FIGS. 1 to 5 are assigned identical symbols and shall not be discussed.

As shown in FIG. 9, the electrically powered steering apparatus 100 of the variation example features the torque assist mechanism 40A in place of the torque assist mechanism 40 (see FIG. 1) of the preceding embodiment. Other arrangements are the same as in the embodiment shown in FIGS. 1 to 5.

To describe in detail, the torque assist mechanism 40A comprises a magnetostrictive sensor 41, a controller 42, an electric motor 101, and a worm gear mechanism 102. The magnetostrictive sensor 41 and the controller 42 are of the same design as in the embodiment.

The electric motor 101 is of substantially the same design as the electric motor 43 of the embodiment, except for being separate from the rack shaft 26. This electric motor 101 generates a motor torque (assist torque) that corresponds to the aforementioned steering torque on the basis of a control signal from the controller 42.

The worm gear mechanism 102 is a power transmission mechanism (power assist mechanism) comprising a worm 103 linked to the motor shaft 101a of the electric motor 101; and a worm wheel 104 integrally joined to the pinion shaft 62.

With this electrically powered steering apparatus 100, a steering torque transmitted to the torque-side shaft 61 can be detected by the magnetostrictive torque sensor 41; a motor torque (assist torque) that corresponds to the steering torque can be generated by the electric motor 101; and this motor torque can be transmitted to the pinion shaft 62 via the worm gear mechanism 102. That is, the combined torque of the steering torque and the additional motor torque is transmitted to the rack shaft 26 via the torque transmission shaft 24 and the rack-and-pinion mechanism 25. The steered wheels 31, 31 are steered by the combined torque transmitted via the rack shaft 26.

In this way, the motor torque is transmitted from the worm wheel 104 to the pinion 32 via the pinion shaft 62 only. The strength required of the torque-side shaft 61 can be made correspondingly lower.

The arrangements taught in modified examples 1, 2, and 3 may be employed for the torque transmission shaft 24 of the electrically powered steering apparatus 100 of this variation example.

In the present invention, it is sufficient for the electrically powered steering apparatus 10, 100 to have an arrangement whereby at least one torque selected from a steering torque and a motor torque generated by the electric motor 43, 101 in accordance with steering is transmitted to the rack shaft 36 via the torque transmission shaft 24, 24A-24C and the rack-and-pinion mechanism 25; and to further have an arrangement whereby the at least one torque transmitted to the torque transmission shaft 24, 24A-24C is sensed by the magnetostrictive sensor 41.

For example, the electrically powered steering apparatus 10, 100 may employ an arrangement of a so-called steer-by-wire system, in which the torque transmission shaft 24, 24A-24C and the rack shaft 26 are mechanically separated from the steering wheel 21.

For example, the electrically powered steering apparatus 100 of the variation example shown in FIG. 9 can be constituted as a steer-by-wire system, by means of the arrangements of (1) to (5) following.

(1) Dispensing with the swivel joints 23, 23 so that the torque transmission shaft 24 is mechanically separate from the steering wheel 21.

(2) Providing a new steering angle sensor 111 for sensing the steering level (steering input) of the steering wheel 21.

(3) Providing an arrangement whereby the controller 42 generates a control signal on the basis of sensor signals sensed by the steering angle sensor 111 and the magnetostrictive sensor 41.

(4) Providing an arrangement whereby the electric motor 101 generates a motor torque that corresponds to the steering level on the basis of the control signal of the controller 42.

(5) Sending by the magnetostrictive sensor 41 only the motor torque transmitted from the electric motor 101 to the torque transmission shaft 24.

The steering wheel 21 preferably has a new electric motor for imparting a steering reaction force to the steering wheel 21, and a new torque sensor for sensing the reaction force (torque). The term “steering reaction force” refers to steering resistance applied to the steering wheel 21 in the direction of turning.

In the present invention, the steering member is not limited to a steering wheel 21.

The linking structure of the torque-side shaft 61 and the pinion shaft 62 is not limited to linking by means of a pin 67, and any arrangement for linking the two together is acceptable. For example, linking by a screw is acceptable. Alternatively, the mating shaft portion 63 and the mating hole 65 may be dispensed with, and the torque-side shaft 61 and pinion shaft 62 may instead be linked together by being joined through friction welding or the like.

In the electrically powered steering apparatus 10 of the embodiment shown in FIGS. 1 and 2, the power transmission mechanism for transmitting power from the electric motor 43 to the rack shaft 26 is not limited to a ball screw 44, and a worm gear mechanism could be substituted, for example. A structure combining a ball screw 44 and a worm gear mechanism can be used as well.

The electrically powered steering apparatus 10, 100 of the present invention is suitable as an arrangement for transmitting a steering torque and a motor torque to the rack shaft 26 via the torque transmission shaft 24, 24A-24C and the rack-and-pinion mechanism 25, wherein a magnetostrictive sensor 41 is provided for sensing the torque transmitted to the torque transmission shaft 24, 24A-24C.

Obviously, various minor changes and modifications of the present invention are possible in light of the above teaching. It is therefore to be understood that within the scope of the appended claims the invention may be practiced otherwise than as specifically described.

What is claimed is:

1. A method for constructing an electrically powered steering apparatus for transmission of torque to steered wheels via a rack-and-pinion mechanism, comprising:
providing a torque-side shaft having a magnetostrictive torque sensor disposed thereon, wherein the magnetostrictive torque sensor includes a pair of vapor-plated magnetostrictive film portions imparted with residual strain in mutually opposite directions and formed on an outside peripheral face of the torque-side shaft;
subjecting the torque-side shaft to a first heat treatment process in order to establish a direction of magnetostriction of the magnetostrictive film portions;
providing a pinion shaft having a pinion of the rack-and-pinion mechanism;
subjecting the torque-side shaft to a second heat treatment process in order to assure sufficient strength needed for torque transmission; and
connecting the torque-side shaft and the pinion shaft together after the first and second heat treatment processes are completed, such that the torque-side shaft and the pinion shaft are concentric with each other and restrict one another in terms of relative rotation and relative movement in an axial direction.
